(19) United States
(12) Patent Application Publication
(10) Pub. No.: US 2026/0006690 A1
(43) Pub. Date: Jan. 1, 2026

(54) HIGH-PRECISION LED CURRENT DETECTION CIRCUIT

(71) Applicant: KeWei YING, Fujian (CN)

(72) Inventor: KeWei YING, Fujian (CN)

(21) Appl. No.: 18/945,574

(22) Filed: Nov. 13, 2024

(30) Foreign Application Priority Data
Jun. 28, 2024 (CN) 2024108652100

(51) Int. Cl. H05B 45/14; G01R 1/30; G01R 19/00

(52) U.S. Cl. CPC H05B 45/14; G01R 1/30; G01R 19/0038

(57) ABSTRACT

A high-precision LED current detection circuit, including a current sampling circuit and a comparison and determination circuit; the current sampling circuit is configured to collect an output current of the LED light source; the comparison and determination circuit is configured to determine whether the output current of the LED light source is within a preset normal range or not.

### BACKGROUND OF THE INVENTION

The present invention relates to the field of LEDs, and in particular, to a high-precision LED current detection circuit.

Most of the lamps used by the existing vehicles (such as new energy vehicles and automobiles) are LED lamps; however, due to complicated and nasty environments in which a vehicle is driven, the LED driving circuit on the vehicle is often subject to various disturbances and challenges. To determine whether the LED driving circuit is operating normally, the vehicle is typically equipped with an LED current detection circuit for detecting whether the output current of the LED light source of the LED driving circuit is normal or not.

With reference to FIG. 1, an existing LED driving circuit generally comprises an LED light source′, an operational amplifier OP1′, a resistor R1′, a MOS transistor MN1′, a MOS transistor MN0′, a dimmer switch S_{PWM}′, and a power transistor array′; the LED light source′ comprises at least one LED lamp bead led′, a positive electrode of the LED light source′ is connected to a driving power supply V_{LED}′, a negative electrode of the LED light source′ is connected to a drain of the MOS transistor MN0′, a gate of the MOS transistor MN0′ is connected to an output terminal of the operational amplifier OP1′, a source of the MOS transistor MN0′ is connected to a drain terminal of the power transistor array′ and an inverting input terminal of the operational amplifier OP1′, a source terminal of the power transistor array′ is grounded, a gate terminal of the power transistor array′ is connected to a first terminal of the dimmer switch S_{PWM}′, a control terminal of the dimmer switch S_{PWM}′ is connected to a dimmer signal DS_{PWM}′, a second terminal of the dimmer switch S_{PWM}′ and a gate of the MOS transistor MN1′ are both connected to a reference current signal Ir′, a source of the MOS transistor MN1′ is grounded, a drain of the MOS transistor MN1′ is connected to a first terminal of the resistor R1′ and a non-inverting input terminal of the operational amplifier OP1′, and a second terminal of the resistor R1′ is connected to the reference current signal Ir′; the power transistor array′ comprises 2ⁿ number of identical power transistor units′, each of the power transistor units' comprises a power transistor MN_i′ and a control switch S_i′, a drain of the power transistor MN_i′ is connected to the drain terminal of the power transistor array′, a gate of the power transistor MN_i′ is connected to a first terminal of the control switch S_i′, a second terminal of the control switch S_i′ is connected to the gate terminal of the power transistor array′, a source of the power transistor MN_i′ is connected to the source terminal of the power transistor array′, a control terminal of the control switch S_i′ is connected to a control signal CS_i′, i′ is an integer from 1 to 2^{n′}, and ^{n′} is a positive integer. With reference to FIG. 1, an existing current detection circuit comprises a MOS transistor MNs′, a MOS transistor MP0′, a MOS transistor MP1′, a resistor R2′, a comparator CMPH′, a comparator CMPL′, and an OR gate U1′; a gate of the MOS transistor MNs' is connected to the gate terminal of the power transistor array′, a source of the MOS transistor MNs' is grounded, a drain of the MOS transistor MNs' is connected to a gate and a drain of the MOS transistor MP0′ and a gate of the MOS transistor MP1′, a source of the MOS transistor MP0′ and a source of the MOS transistor MP1′ are connected to a control power supply VDD′, a drain of the MOS transistor MP1′ is connected to a first terminal of the resistor R2′, a non-inverting input terminal of the comparator CMPH′, and an inverting input terminal of the comparator CMPL′, a second terminal of the resistor R2′ is grounded, an inverting input terminal of the comparator CMPH′ is connected to an upper limit threshold voltage signal V_{Hth}′, a non-inverting input terminal of the comparator CMPL′ is connected to a lower limit threshold voltage signal V_{Lth}′, and an output terminal of the comparator CMPH′ and an output terminal of the comparator CMPL′ are connected to two input terminals of the OR gate U1′ respectively.

The working principle of the existing LED current detection circuit is as follows: The MOS transistor MNs' can mirror an output current of the MOS transistor MN1′, and the MOS transistor MP0′, the MOS transistor MP1′, and the resistor R2′ can convert a mirrored current signal of the MOS transistor MNs' into a corresponding monitoring voltage signal Vs′; the comparator CMPH′ and the comparator CMPL′ compare the monitoring voltage signal Vs' with the upper limit threshold voltage signal V_{Hth}′ and the lower limit threshold voltage signal V_{Lth}′, and if a voltage of the monitoring voltage signal Vs' is greater than a voltage of the upper limit threshold voltage signal V_{Hth}′ or the voltage of the monitoring voltage signal Vs' is less than a voltage of the lower limit threshold voltage signal V_{Lth}′, it is determined that an output current of the LED light source′ exceeds a preset normal range; in this case, one of the comparator CMPH′ and the comparator CMPL′ outputs a high level signal to the OR gate U1′, such that the OR gate U1′ outputs the high level signal to subsequent systems to enable the subsequent systems to know that the output current of the LED light source′ is abnormal.

The existing LED current detection circuit has the following defects:

1. The voltage between the source terminal and the drain terminal of the power transistor array′ is not completely equal to the source-drain voltage of the MOS transistor MNs′. Especially, when the current of the reference current signal Ir′ varies, the voltage between the source terminal and the drain terminal of the power transistor array′ will vary accordingly, which causes a greater deviation in the mirrored current mirrored by the MOS transistor MNs′.

2. The MOS transistor MNs' and the power transistor array′ are connected in parallel; when the MOS transistor MN1′ is operating normally but the power transistors MN_i′ of the power transistor array′ are partially or entirely aged, the output current of the LED light source′ will become abnormal, but the mirrored current mirrored by the MOS transistor MNs' is still within a normal range, thereby causing omission of abnormal information which should have been reported to the subsequent systems.

3. The output current of the LED light source′ varies correspondingly with a number of control switch S_i′ in the power transistor array′, therefore, the voltage of the upper limit threshold voltage signal V_{Hth}′ and the voltage of the lower limit threshold voltage signal V_{Lth}′ need to be adjusted correspondingly according to the number of control switch S_i′ in the power transistor array′, thereby increasing the design difficulty.

In view of the above problems, there is a need to develop a high-precision LED current detection circuit to overcome at least one of the above defects.

### BRIEF SUMMARY OF THE INVENTION

It is an object of the present invention is to provide a high-precision LED current detection circuit to overcome at least one of the defects mentioned in the background.

To achieve the above object, the present invention provides the following technical solutions:

A high-precision LED current detection circuit, which is configured to cooperate with an LED driving circuit, wherein the LED driving circuit comprises an LED light source, an operational amplifier OP1, a resistor R1, a MOS transistor MN1, a MOS transistor MN0, a dimmer switch S_{PWM}, and a power transistor array; the LED light source comprises at least one LED lamp bead led; a positive electrode of the LED light source is connected to a driving power supply V_{LED}; a negative electrode of the LED light source is connected to a drain of the MOS transistor MN0; a gate of the MOS transistor MN0 is connected to an output terminal of the operational amplifier OP1, a source of the MOS transistor MN0 is connected to a drain terminal of the power transistor array and an inverting input terminal of the operational amplifier OP1; a source terminal of the power transistor array is grounded; a gate terminal of the power transistor array is connected to a first terminal of the dimmer switch S_{PWM}; a control terminal of the dimmer switch S_{PWM} is connected to a dimmer signal DS_{PWM}; a second terminal of the dimmer switch S_{PWM} and a gate of the MOS transistor MN1 are both connected to a reference current signal Ir; a source of the MOS transistor MN1 is grounded; a drain of the MOS transistor MN1 is connected to a first terminal of the resistor R1 and a non-inverting input terminal of the operational amplifier OP1; a second terminal of the resistor R1 is connected to the reference current signal Ir; the power transistor array comprises 2n number of identical power transistor units; each of the power transistor units comprises a power transistor MN_i and a control switch S_i; a drain of the power transistor MN_i is connected to a drain terminal of the power transistor array; a gate of the power transistor MN_i is connected to a first terminal of the control switch S_i; a second terminal of the control switch S_i is connected to a gate terminal of the power transistor array; a control terminal of the control switch S_i is connected to a control signal CS_i; i in each of the power transistor units is an integer from 1 to 2ⁿ, and n is a positive integer;
the high-precision LED current detection circuit comprises a current sampling circuit and a comparison and determination circuit;
the current sampling circuit comprises a MOS transistor MNs, a MOS transistor MNf, and an operational amplifier OP2; a non-inverting input terminal of the operational amplifier OP2 is configured to be connected to the drain of the MOS transistor MN0; an inverting input terminal of the operational amplifier OP2 is connected to a source of the MOS transistor MNf and a drain of the MOS transistor MNs; a drain of the MOS transistor MNf is connected to an input terminal of the comparison and determination circuit; a gate of the MOS transistor MNs is configured to be connected to the gate of the MOS transistor MN0; a source of the MOS transistor MNs is configured to be connected to the source of the MOS transistor MN0.

The comparison and determination circuit comprises a first current mirror, a second current mirror, a third current mirror, a reference transistor array, a comparator CMPH, a comparator CMPL, a MOS transistor MNL, a MOS transistor MNH, and an OR gate U1; a mirrored terminal of the first current mirror is connected to an input terminal of the comparison and determination circuit; a mirroring terminal of the first current mirror is connected to a non-inverting input terminal of the comparator CMPH, an inverting input terminal of the comparator CMPL, and a drain terminal of the reference transistor array; a mirrored terminal of the second current mirror is connected to a lower limit threshold current signal I_{Lth}; a mirroring terminal of the second current mirror is connected to a non-inverting input terminal of the comparator CMPL and a drain of the MOS transistor MNL; a mirrored terminal of the third current mirror is connected to an upper limit threshold current signal I_{Hth}; a mirroring terminal of the third current mirror is connected to an inverting input terminal of the comparator CMPH and a drain of the MOS transistor MNH; a gate of the MOS transistor MNL and a gate of the MOS transistor MNH are connected to a gate terminal of the reference transistor array; the gate terminal and the drain terminal of the reference transistor array are in short circuit; a source terminal of the reference transistor array, a source of the MOS transistor MNL, and a source of the MOS transistor MNH are grounded.

The reference transistor array comprises 2n number of identical reference transistor units, and each reference transistor unit comprises a reference transistor MNr_i and a reference switch K_i; a drain of the reference transistor MNr_i is connected to the drain terminal of the reference transistor array; a gate of the reference transistor MNr_i is connected to a first terminal of the reference switch K_i; a second terminal of the reference switch K_i is connected to the gate terminal of the reference transistor array; a source of the reference transistor MNr_i is connected to the source terminal of the reference transistor array; a control terminal of the reference switch K_i is connected to the same control signal CS_i provided for a respective power transistor unit of the power transistor array.

The first current mirror comprises a MOS transistor MP0 and a MOS transistor MP1; a gate and a drain of the MOS transistor MP0 and a gate of the MOS transistor MP1 are connected to the mirrored terminal of the first current mirror; a source of the MOS transistor MP0 and a source of the MOS transistor MP1 are connected to a control power supply VDD; a drain of the MOS transistor MP1 is connected to the mirroring terminal of the first current mirror.

The second current mirror comprises a MOS transistor MP2 and a MOS transistor MP3; a gate and a drain of the MOS transistor MP2 and a gate of the MOS transistor MP3 are connected to the mirrored terminal of the second current mirror; a source of the MOS transistor MP2 and a source of the MOS transistor MP3 are connected to the control power supply VDD; a drain of the MOS transistor MP3 is connected to the mirroring terminal of the second current mirror.

The third current mirror comprises a MOS transistor MP4 and a MOS transistor MP5; a gate and a drain of the MOS transistor MP4 and a gate of the MOS transistor MP5 are connected to the mirrored terminal of the third current mirror; a source of the MOS transistor MP4 and a source of the MOS transistor MP5 are connected to the control power supply VDD; a drain of the MOS transistor MP5 is connected to the mirroring terminal of the third current mirror.

By using the above technical solutions, the present invention has the following advantageous characteristics:

1. The high-precision LED current detection circuit of the present invention comprises a current sampling circuit and a comparison and determination circuit; the current sampling circuit is configured to collect an output current of the LED light source; the comparison and determination circuit is configured to determine whether the output current of the LED light source is within a preset normal range or not.

2. The MOS transistor MNs of the current sampling circuit is configured to mirror the output current of the LED light source (namely a drain current of the MOS transistor MN0) in real-time according to a certain mirroring proportion, thereby achieving the effect of sampling the output current of the LED light source in real-time; the MOS transistor MNf and the operational amplifier OP2 form a feedback loop, such that a source-drain voltage of the MOS transistor MNs is equal to a source-drain voltage of the MOS transistor MN0, thereby ensuring mirroring precision when the MOS transistor MNs mirrors the output current of the LED light source; accordingly, a monitoring current signal Is obtained by mirroring the output current of the LED light source by the MOS transistor MNs can better reflect the output current of the LED light source; in addition, the MOS transistor MNs and the power transistor array are connected in series, such that a current abnormity of the power transistor array can be directly reflected at the monitoring current signal Is of the MOS transistor MNs, thereby solving the problem of omission of abnormal information reporting in the existing LED current detection circuit.

3. The working principle of the comparison and determination circuit is as follows:
the first current mirror can mirror the monitoring current signal Is according to a certain mirroring proportion to obtain a first mirrored current signal I1; the second current mirror can mirror the lower limit threshold current signal I_{Lth} according to a certain mirroring proportion to obtain a second mirrored current signal I2; the third current mirror can mirror the upper limit threshold current signal I_{Hth} according to a certain mirroring proportion to obtain a third mirrored current signal I3; the first mirrored current signal I1 is converted into a monitoring voltage signal Vs through the reference transistor array and is then inputted into the non-inverting input terminal of the comparator CMPH and the inverting input terminal of the comparator CMPL; the second mirrored current signal I2 is converted into a lower limit threshold voltage signal V_{CL} through the MOS transistor MNL and is then inputted into the non-inverting input terminal of the comparator CMPL; the third mirrored current signal I3 is converted into an upper limit threshold voltage signal V_{CH} through the MOS transistor MNH and is then inputted into the inverting input terminal of the comparator CMPH;
when the output current of the LED light source is normal, a current value of the output current of the LED light source is between a current value of the upper limit threshold current signal I_{Hth} and a current value of the lower limit threshold current signal I_{Lth}, and a voltage value of the lower limit threshold voltage signal V_{CL} is lower than a voltage value of the monitoring voltage signal Vs, and a voltage value of the upper limit threshold voltage signal V_{CH} is higher than the voltage value of the monitoring voltage signal Vs; accordingly, both the comparator CMPH and the comparator CMPL output low level signals to the OR gate U1, so that the OR gate U1 outputs the low level signals;
when the current value of the output current of the LED light source is lower than the current value of the lower limit threshold current signal I_{Lth}, a current value of a drain current of the MOS transistor MNL ought to be lower than a current value of the second mirrored current signal I2 due to a current mirror formed by the MOS transistor MNL with the reference transistor array will now have to be made identical to the current value of the second mirrored current signal I2 because of the series connection between the second current mirror and the MOS transistor MNL, to achieve this, the second current mirror will pull up the voltage value of the lower limit threshold voltage signal V_{CL} (that is to say, a drain-source voltage of the MOS transistor MP3 will be greatly reduced to enable the MOS transistor MP3 to enter a linear region), such that the voltage value of the lower limit threshold voltage signal V_{CL} is greater than the voltage value of the monitoring voltage signal Vs, and thus the comparator CMPL outputs a high level signal to the OR gate U1, enabling the OR gate U1 to output the high level signal;
when the current value of the output current of the LED light source is higher than the current value of the upper limit threshold current signal IHih, a current value of a drain current of the MOS transistor MNH ought to be higher than a current value of the third mirrored current signal I3 due to a current mirror formed by the MOS transistor MNH with the reference transistor array will now have to be made identical to the current value of the third mirrored current signal I3 because of the series connection between the third current mirror and the MOS transistor MNH, to achieve this, a drain-source voltage of the MOS transistor MNH will be greatly reduced to enable the MOS transistor MNH to enter a linear region, thereby pulling down the voltage value of the upper limit threshold voltage signal V_{CH}; in this case, the voltage value of the upper limit threshold voltage signal V_{CH} is lower than the voltage value of the monitoring voltage signal Vs, and thus the comparator CMPH outputs a high level signal to the OR gate U1, enabling the OR gate U1 to output the high level signal;
the reference transistor array and the power transistor array of the present invention use the same structural arrangements, and the reference switch K_i of each of the reference transistor units in the reference transistor array and the control switch S_i of a corresponding power transistor unit in the power transistor array are controlled by a same control signal CS_i, such that the reference transistor array and the power transistor array have a same on-off state; therefore, given that the lower limit threshold current signal I_{Lth} and the upper limit threshold current signal I_{Hth} remain unchanged, the monitoring voltage signal Vs, the lower limit threshold voltage signal V_{CL}, and the upper limit threshold voltage signal V_{CH} will vary in a same proportion according to the on-off state of the power transistor array, and thus ensuring that the high-precision LED current detection circuit of the present invention can still effectively detect whether the output current of the LED light source is normal or not, thereby effectively improving a detection range of the high-precision LED current detection circuit of the present invention and reducing the difficulty of circuit design.

### BRIEF DESCRIPTION OF THE DRAWINGS

FIG. 1 is a schematic circuit diagram of an existing LED driving circuit and an existing LED current detection circuit.

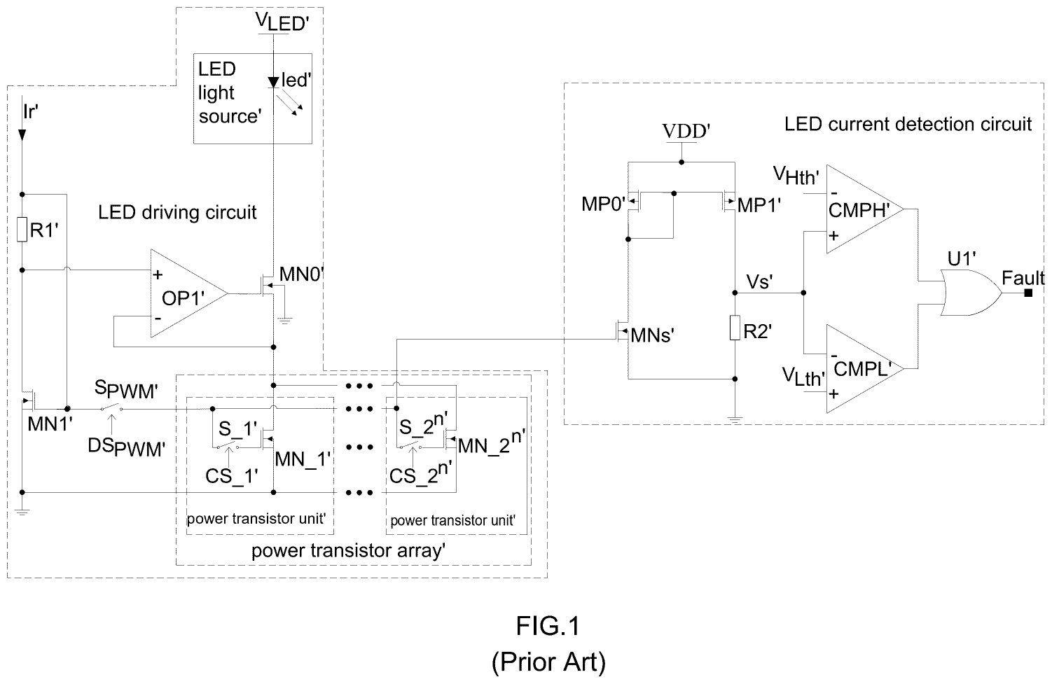

FIG. 2 is a schematic circuit diagram of an LED driving circuit and a high-precision LED current detection circuit according to the present invention.

### DETAILED DESCRIPTION OF THE INVENTION

To further explain the technical solutions of the present invention, a detailed description of the present invention is provided below through specific embodiments.

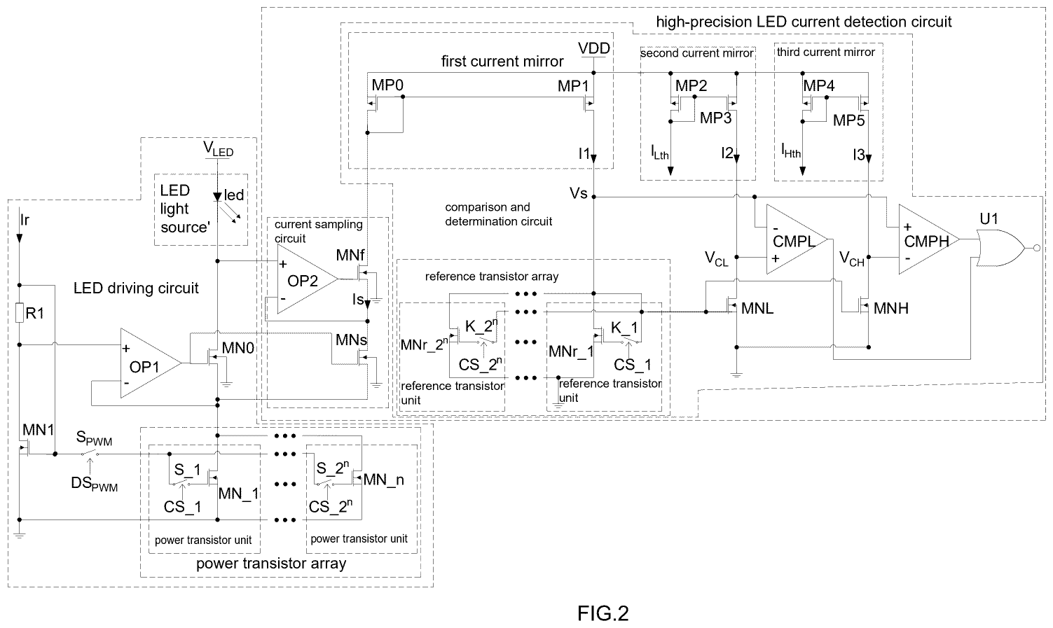

As shown in FIG. 2, the present invention provides a high-precision LED current detection circuit, which is configured to cooperate with an LED driving circuit, wherein the LED driving circuit comprises an LED light source, an operational amplifier OP1, a resistor R1, a MOS transistor MN1, a MOS transistor MN0, a dimmer switch S_{PWM}, and a power transistor array; the LED light source comprises at least one LED lamp bead led; a positive electrode of the LED light source is connected to a driving power supply V_{LED}; a negative electrode of the LED light source is connected to a drain of the MOS transistor MN0; a gate of the MOS transistor MN0 is connected to an output terminal of the operational amplifier OP1, a source of the MOS transistor MN0 is connected to a drain terminal of the power transistor array and an inverting input terminal of the operational amplifier OP1; a source terminal of the power transistor array is grounded; a gate terminal of the power transistor array is connected to a first terminal of the dimmer switch S_{PWM}; a control terminal of the dimmer switch S_{PWM} is connected to a dimmer signal DS_{PWM}; a second terminal of the dimmer switch S_{PWM} and a gate of the MOS transistor MN1 are both connected to a reference current signal Ir; a source of the MOS transistor MN1 is grounded; a drain of the MOS transistor MN1 is connected to a first terminal of the resistor R1 and a non-inverting input terminal of the operational amplifier OP1; a second terminal of the resistor R1 is connected to the reference current signal Ir; the power transistor array comprises 2ⁿ number of identical power transistor units; each of the power transistor units comprises a power transistor MN_i and a control switch S_i; a drain of the power transistor MN_i is connected to a drain terminal of the power transistor array; a gate of the power transistor MN_i is connected to a first terminal of the control switch S_i; a second terminal of the control switch S_i is connected to a gate terminal of the power transistor array; a control terminal of the control switch S_i is connected to a control signal CS_i; i in each of the power transistor units is an integer from 1 to 2n, and n is a positive integer.

With reference to FIG. 2, the high-precision LED current detection circuit of the present invention comprises a current sampling circuit and a comparison and determination circuit; the current sampling circuit is configured to collect an output current of the LED light source; the comparison and determination circuit is configured to determine whether the output current of the LED light source is within a preset normal range or not.

With reference to FIG. 2, specifically, the current sampling circuit comprises a MOS transistor MNs, a MOS transistor MNf, and an operational amplifier OP2; a non-inverting input terminal of the operational amplifier OP2 is configured to be connected to the drain of the MOS transistor MN0; an inverting input terminal of the operational amplifier OP2 is connected to a source of the MOS transistor MNf and a drain of the MOS transistor MNs; a drain of the MOS transistor MNf is connected to an input terminal of the comparison and determination circuit; a gate of the MOS transistor MNs is configured to be connected to the gate of the MOS transistor MN0; a source of the MOS transistor MNs is configured to be connected to the source of the MOS transistor MN0.

The working principle of the current sampling circuit is as follows: The MOS transistor MNs is configured to mirror the output current of the LED light source (namely a drain current of the MOS transistor MN0) in real-time according to a certain mirroring proportion, thereby achieving the effect of sampling the output current of the LED light source in real-time; the MOS transistor MNf and the operational amplifier OP2 form a feedback loop, such that a source-drain voltage of the MOS transistor MNs is equal to a source-drain voltage of the MOS transistor MN0, thereby ensuring mirroring precision when the MOS transistor MNs mirrors the output current of the LED light source; accordingly, a monitoring current signal Is obtained by mirroring the output current of the LED light source by the MOS transistor MNs can better reflect the output current of the LED light source; in addition, the MOS transistor MNs and the power transistor array are connected in series, such that a current abnormity of the power transistor array can be directly reflected at the monitoring current signal Is of the MOS transistor MNs, thereby solving the problem of omission of abnormal information reporting in the existing LED current detection circuit.

With reference to FIG. 2, the comparison and determination circuit comprises a first current mirror, a second current mirror, a third current mirror, a reference transistor array, a comparator CMPH, a comparator CMPL, a MOS transistor MNL, a MOS transistor MNH, and an OR gate U1; a mirrored terminal of the first current mirror is connected to an input terminal of the comparison and determination circuit; a mirroring terminal of the first current mirror is connected to a non-inverting input terminal of the comparator CMPH, an inverting input terminal of the comparator CMPL, and a drain terminal of the reference transistor array; a mirrored terminal of the second current mirror is connected to a lower limit threshold current signal I_{Lth}; a mirroring terminal of the second current mirror is connected to a non-inverting input terminal of the comparator CMPL and a drain of the MOS transistor MNL; a mirrored terminal of the third current mirror is connected to an upper limit threshold current signal I_{Hth}; a mirroring terminal of the third current mirror is connected to an inverting input terminal of the comparator CMPH and a drain of the MOS transistor MNH; a gate of the MOS transistor MNL and a gate of the MOS transistor MNH are connected to a gate terminal of the reference transistor array; the gate terminal and the drain terminal of the reference transistor array are in short circuit; a source terminal of the reference transistor array, a source of the MOS transistor MNL, and a source of the MOS transistor MNH are grounded.

With reference to FIG. 2, the reference transistor array comprises 2″ number of identical reference transistor units, and each reference transistor unit comprises a reference transistor MNr_i and a reference switch K_i; a drain of the reference transistor MNr_i is connected to the drain terminal of the reference transistor array; a gate of the reference transistor MNr_i is connected to a first terminal of the reference switch K_i; a second terminal of the reference switch K_i is connected to the gate terminal of the reference transistor array; a source of the reference transistor MNr_i is connected to the source terminal of the reference transistor array; a control terminal of the reference switch K_i is connected to the same control signal CS_i provided for a respective power transistor unit of the power transistor array; as same as the power transistor units, i mentioned herein in each of the reference transistor units is an integer from 1 to 2ⁿ, and n is a positive integer.

With reference to FIG. 2, the first current mirror comprises a MOS transistor MP0 and a MOS transistor MP1; a gate and a drain of the MOS transistor MP0 and a gate of the MOS transistor MP1 are connected to the mirrored terminal of the first current mirror; a source of the MOS transistor MP0 and a source of the MOS transistor MP1 are connected to a control power supply VDD; a drain of the MOS transistor MP1 is connected to the mirroring terminal of the first current mirror.

With reference to FIG. 2, the second current mirror comprises a MOS transistor MP2 and a MOS transistor MP3; a gate and a drain of the MOS transistor MP2 and a gate of the MOS transistor MP3 are connected to the mirrored terminal of the second current mirror; a source of the MOS transistor MP2 and a source of the MOS transistor MP3 are connected to the control power supply VDD; a drain of the MOS transistor MP3 is connected to the mirroring terminal of the second current mirror.

With reference to FIG. 2, the third current mirror comprises a MOS transistor MP4 and a MOS transistor MP5; a gate and a drain of the MOS transistor MP4 and a gate of the MOS transistor MP5 are connected to the mirrored terminal of the third current mirror; a source of the MOS transistor MP4 and a source of the MOS transistor MP5 are connected to the control power supply VDD; a drain of the MOS transistor MP5 is connected to the mirroring terminal of the third current mirror.

The working principle of the comparison and determination circuit is as follows:

The first current mirror can mirror the monitoring current signal Is according to a certain mirroring proportion to obtain a first mirrored current signal I1; the second current mirror can mirror the lower limit threshold current signal I_{Lth} according to a certain mirroring proportion to obtain a second mirrored current signal I2; the third current mirror can mirror the upper limit threshold current signal I_{Hth} according to a certain mirroring proportion to obtain a third mirrored current signal I3; the first mirrored current signal I1 is converted into a monitoring voltage signal Vs through the reference transistor array and is then inputted into the non-inverting input terminal of the comparator CMPH and the inverting input terminal of the comparator CMPL; the second mirrored current signal I2 is converted into a lower limit threshold voltage signal V_{CL} through the MOS transistor MNL and is then inputted into the non-inverting input terminal of the comparator CMPL; the third mirrored current signal I3 is converted into an upper limit threshold voltage signal V_{CH} through the MOS transistor MNH and is then inputted into the inverting input terminal of the comparator CMPH;
when the output current of the LED light source is normal, a current value of the output current of the LED light source is between a current value of the upper limit threshold current signal I_{Hth} and a current value of the lower limit threshold current signal I_{Lth}, and a voltage value of the lower limit threshold voltage signal V_{CL} is lower than a voltage value of the monitoring voltage signal Vs, and a voltage value of the upper limit threshold voltage signal V_{CH} is higher than the voltage value of the monitoring voltage signal Vs; accordingly, both the comparator CMPH and the comparator CMPL output low level signals to the OR gate U1, so that the OR gate U1 outputs the low level signals;
when the current value of the output current of the LED light source is lower than the current value of the lower limit threshold current signal I_{Lth}, a current value of a drain current of the MOS transistor MNL ought to be lower than a current value of the second mirrored current signal I2 due to a current mirror formed by the MOS transistor MNL with the reference transistor array will now have to be made identical to the current value of the second mirrored current signal I2 because of the series connection between the second current mirror and the MOS transistor MNL, to achieve this, the second current mirror will pull up the voltage value of the lower limit threshold voltage signal V_{CL} (that is to say, a drain-source voltage of the MOS transistor MP3 will be greatly reduced to enable the MOS transistor MP3 to enter a linear region), such that the voltage value of the lower limit threshold voltage signal V_{CL} is greater than the voltage value of the monitoring voltage signal Vs, and thus the comparator CMPL outputs a high level signal to the OR gate U1, enabling the OR gate U1 to output the high level signal;
when the current value of the output current of the LED light source is higher than the current value of the upper limit threshold current signal I_{Hth}, a current value of a drain current of the MOS transistor MNH ought to be higher than a current value of the third mirrored current signal I3 due to a current mirror formed by the MOS transistor MNH with the reference transistor array will now have to be made identical to the current value of the third mirrored current signal I3 because of the series connection between the third current mirror and the MOS transistor MNH, to achieve this, a drain-source voltage of the MOS transistor MNH will be greatly reduced to enable the MOS transistor MNH to enter a linear region, thereby pulling down the voltage value of the upper limit threshold voltage signal V_{CH}; in this case, the voltage value of the upper limit threshold voltage signal V_{CH} is lower than the voltage value of the monitoring voltage signal Vs, and thus the comparator CMPH outputs a high level signal to the OR gate U1, enabling the OR gate U1 to output the high level signal.

In the present invention, the reference transistor array and the power transistor array use the same structural arrangements, and the reference switch K_i of each of the reference transistor units in the reference transistor array and the control switch S_i of a corresponding power transistor unit in the power transistor array are controlled by a same control signal CS_i, such that the reference transistor array and the power transistor array have a same on-off state; therefore, given that the lower limit threshold current signal I_{Lth} and the upper limit threshold current signal I_{Hth} remain unchanged, the monitoring voltage signal Vs, the lower limit threshold voltage signal V_{CL}, and the upper limit threshold voltage signal V_{CH} will vary in a same proportion according to the on-off state of the power transistor array, and thus ensuring that the high-precision LED current detection circuit of the present invention can still effectively detect whether the output current of the LED light source is normal or not, thereby effectively improving a detection range of the high-precision LED current detection circuit of the present invention and reducing the difficulty of circuit design.

The above embodiments and illustrations are not intended to limit the form and type of the product of the present invention. Any appropriate variations or modifications made by those of ordinary skills in the art within the scope of the present invention shall be considered as falling within the scope of the patent.

What is claimed is:

1. A high-precision LED current detection circuit, which is configured to cooperate with an LED driving circuit, wherein, the LED driving circuit comprises:
an LED light source, an operational amplifier OP1, a resistor R1, a MOS transistor MN1, a MOS transistor MN0, a dimmer switch S_{PWM}, and a power transistor array; the LED light source comprises at least one LED lamp bead led; a positive electrode of the LED light source is connected to a driving power supply V_{LED}; a negative electrode of the LED light source is connected to a drain of the MOS transistor MN0; a gate of the MOS transistor MN0 is connected to an output terminal of the operational amplifier OP1, a source of the MOS transistor MN0 is connected to a drain terminal of the power transistor array and an inverting input terminal of the operational amplifier OP1; a source terminal of the power transistor array is grounded; a gate terminal of the power transistor array is connected to a first terminal of the dimmer switch S_{PWM}; a control terminal of the dimmer switch S_{PWM} is connected to a dimmer signal DS_{PWM}; a second terminal of the dimmer switch S_{PWM} and a gate of the MOS transistor MN1 are both connected to a reference current signal Ir; a source of the MOS transistor MN1 is grounded; a drain of the MOS transistor MN1 is connected to a first terminal of the resistor R1 and a non-inverting input terminal of the operational amplifier OP1; a second terminal of the resistor R1 is connected to the reference current signal Ir; the power transistor array comprises 2n number of identical power transistor units; each of the power transistor units comprises a power transistor MN_i and a control switch S_i; a drain of the power transistor MN_i is connected to a drain terminal of the power transistor array; a gate of the power transistor MN_i is connected to a first terminal of the control switch S_i; a second terminal of the control switch S_i is connected to a gate terminal of the power transistor array; a control terminal of the control switch S_i is connected to a control signal CS_i; i in each of the power transistor units is an integer from 1 to 2ⁿ, and n is a positive integer;
the high-precision LED current detection circuit is characterized in that:
the high-precision LED current detection circuit comprises a current sampling circuit and a comparison and determination circuit;
the current sampling circuit comprises a MOS transistor MNs, a MOS transistor MNf, and an operational amplifier OP2; a non-inverting input terminal of the operational amplifier OP2 is configured to be connected to the drain of the MOS transistor MN0; an inverting input terminal of the operational amplifier OP2 is connected to a source of the MOS transistor MNf and a drain of the MOS transistor MNs; a drain of the MOS transistor MNf is connected to an input terminal of the comparison and determination circuit; a gate of the MOS transistor MNs is configured to be connected to the gate of the MOS transistor MN0; a source of the MOS transistor MNs is configured to be connected to the source of the MOS transistor MN0.

2. The high-precision LED current detection circuit of claim 1, wherein the comparison and determination circuit comprises a first current mirror, a second current mirror, a third current mirror, a reference transistor array, a comparator CMPH, a comparator CMPL, a MOS transistor MNL, a MOS transistor MNH, and an OR gate U1;
a mirrored terminal of the first current mirror is connected to an input terminal of the comparison and determination circuit; a mirroring terminal of the first current mirror is connected to a non-inverting input terminal of the comparator CMPH, an inverting input terminal of the comparator CMPL, and a drain terminal of the reference transistor array;
a mirrored terminal of the second current mirror is connected to a lower limit threshold current signal I_{Lth}; a mirroring terminal of the second current mirror is connected to a non-inverting input terminal of the comparator CMPL and a drain of the MOS transistor MNL;
a mirrored terminal of the third current mirror is connected to an upper limit threshold current signal I_{Hth}; a mirroring terminal of the third current mirror is connected to an inverting input terminal of the comparator CMPH and a drain of the MOS transistor MNH;
a gate of the MOS transistor MNL and a gate of the MOS transistor MNH are connected to a gate terminal of the reference transistor array; the gate terminal and the drain terminal of the reference transistor array are in short circuit; a source terminal of the reference transistor array, a source of the MOS transistor MNL, and a source of the MOS transistor MNH are grounded.

3. The high-precision LED current detection circuit of claim 2, wherein the reference transistor array comprises 2n number of identical reference transistor units, and each reference transistor unit comprises a reference transistor MNr_i and a reference switch K_i; a drain of the reference transistor MNr_i is connected to the drain terminal of the reference transistor array; a gate of the reference transistor MNr_i is connected to a first terminal of the reference switch K_i; a second terminal of the reference switch K_i is connected to the gate terminal of the reference transistor array; a source of the reference transistor MNr_i is connected to the source terminal of the reference transistor array; a control terminal of the reference switch K_i is connected to the same control signal CS_i provided for a respective power transistor unit of the power transistor array.

4. The high-precision LED current detection circuit of claim 2, wherein the first current mirror comprises a MOS transistor MP0 and a MOS transistor MP1; a gate and a drain of the MOS transistor MP0 and a gate of the MOS transistor MP1 are connected to the mirrored terminal of the first current mirror; a source of the MOS transistor MP0 and a source of the MOS transistor MP1 are connected to a control power supply VDD; a drain of the MOS transistor MP1 is connected to the mirroring terminal of the first current mirror.

5. The high-precision LED current detection circuit of claim 2, wherein the second current mirror comprises a MOS transistor MP2 and a MOS transistor MP3; a gate and a drain of the MOS transistor MP2 and a gate of the MOS transistor MP3 are connected to the mirrored terminal of the second current mirror; a source of the MOS transistor MP2 and a source of the MOS transistor MP3 are connected to the control power supply VDD; a drain of the MOS transistor MP3 is connected to the mirroring terminal of the second current mirror.

6. The high-precision LED current detection circuit of claim 2, wherein the third current mirror comprises a MOS transistor MP4 and a MOS transistor MP5; a gate and a drain of the MOS transistor MP4 and a gate of the MOS transistor MP5 are connected to the mirrored terminal of the third current mirror; a source of the MOS transistor MP4 and a source of the MOS transistor MP5 are connected to the control power supply VDD; a drain of the MOS transistor MP5 is connected to the mirroring terminal of the third current mirror.
